(19) United States
(12) Patent Application Publication
(10) Pub. No.: US 2013/0197836 A1
(43) Pub. Date: Aug. 1, 2013

(54) VOLTAGE AND CURRENT MEASURING DEVICE

(71) Applicants: WEI-YAO CHENG, TAIPEI CITY (TW); CHING-FENG HSIEH, TAIPEI CITY (TW)

(72) Inventors: WEI-YAO CHENG, TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/446,453

(22) Filed: Apr. 13, 2012

(30) Foreign Application Priority Data
Jan. 31, 2012 (TW) 101103126

(51) Int. Cl. G06F 19/00; G01R 19/165

(52) U.S. Cl. 702/64

(57) ABSTRACT

A voltage and current measuring device includes a plurality of voltage measuring modules, a plurality of one-way current measuring modules, a plurality of two-way current measuring modules, a voltage transformation module, a communication interface module, and a processor. The modules are integrated to provide different ways of measuring voltage and current concurrently, enable peripheral expansion, and facilitate power supply. Hence, the device features integration and versatility, speeds up a measurement process, and cuts production costs.

### CROSS-REFERENCE TO RELATED APPLICATION

This non-provisional application claims priority under 35 U.S.C. §119(a) on Patent Application No(s). 101103126 filed in Taiwan, R.O.C. on Jan. 31, 2012, the entire contents of which are hereby incorporated by reference.

### FIELD OF TECHNOLOGY

The present invention relates to measurement devices, and more particularly, to an integrated voltage and current measuring device.

### BACKGROUND

A conventional multimeter that can be connected to a computer usually has only one test port and can only perform a single test in each instance. Furthermore, when measuring voltage or current, the conventional multimeter uses a constant partial voltage or a constant shunt resistance, thereby allowing no room for changes in the range of measurement.

The related prior art is so limited that the time taken to test any objects under test increases with the quantity thereof Furthermore, the related prior art is so inefficient that, in some circumstances, two or more conventional multimeters are required to test two or more objects under test. Last but not least, the conventional multimeter is expensive and thus contributes to high production costs.

### SUMMARY

It is an objective of the present invention to measure voltage and current concurrently.

Another objective of the present invention is to speed up measurement of voltage and current.

Yet another objective of the present invention is to provide a voltage and current measuring device that is integrated, simplified, and compact.

In order to achieve the above and other objectives, the present invention provides a voltage and current measuring device for receiving a power supply, performing voltage and current measurement based on an incoming plurality of voltage and current signals under test, and sending a measurement result to a computer, the voltage and current measuring device having a preset processor voltage level, the voltage and current measuring device comprising: a plurality of voltage measuring modules each having a partial voltage resistance unit and converting an incoming voltage signal under test into a voltage measurement signal to be calculated, wherein the partial voltage resistance unit prevents a voltage level of the voltage measurement signal to be calculated from exceeding the preset processor voltage level; a plurality of current measuring modules each converting an incoming current signal under test into a current measurement signal to be calculated; a voltage transformation module for receiving and transforming the power supply so as to provide a plurality of voltages of different voltage levels; a communication interface module comprising a computer communication interface for connection with the computer; and a processor connected to the voltage measuring modules, the current measuring modules, the voltage transformation module, and the communication interface module, operating under the preset processor voltage level, performing voltage measurement on any one or more of the voltage signals under test which has or have a voltage level lower than the preset processor voltage level, receiving the voltage measurement signals to be calculated so as to calculate a measured voltage level, receiving the current measurement signals to be calculated so as to calculate a measured current level, and generating the measurement result.

In an embodiment, the partial voltage resistance unit of the voltage measuring modules is a variable resistance unit.

In an embodiment, the communication interface module comprises a plurality of additional function expansion interfaces to be connected with at least a peripheral control device. The additional function expansion interfaces comprise a plurality of universal asynchronous receivers-transmitters UART.

In an embodiment, the current measuring modules comprise a plurality of one-way current measuring modules which are at least one of a plurality of one-way current measuring modules and a plurality of two-way current measuring modules. The plurality of one-way current measuring modules each convert the incoming current signal under test into a one-way current measurement signal to be calculated, wherein the one-way current measuring modules operate when the positive/negative input of the incoming current signal under test is correctly connected to the positive/negative pole of the one-way current measuring modules. The plurality of two-way current measuring modules each convert the incoming current signal under test into a two-way current measurement signal to be calculated, wherein the two-way current measuring modules operate, regardless of whether the positive/negative input of the incoming current signal under test is correctly connected to the positive/negative pole of the two-way current measuring modules.

In an embodiment, the one-way current measuring modules are each a high-precision current-to-voltage converter or a low-precision current-to-voltage converter. The high-precision current-to-voltage converter has a first resistance unit and a high-precision current-to-voltage conversion IC. The low-precision current-to-voltage converter has a second resistance unit and a low-precision current-to-voltage conversion IC, wherein the resistance level of the first resistance unit is higher than the resistance level of the second resistance unit. The boosting ratio of the high-precision current-to-voltage conversion IC is larger than the boosting ratio of the low-precision current-to-voltage conversion IC.

In an embodiment, the two-way current measuring modules each comprise a shunt resistance unit, a first low-precision current-to-voltage conversion IC, a second low-precision current-to-voltage conversion IC, and a subtracter. The shunt resistance unit manifests a preset shunt resistance level, receives the current signal under test and changes a current level thereof to a preset current range, and has a first output end and a second output end. The first low-precision current-to-voltage conversion IC converts the current signal under test with the changed current level into a first voltage signal, has a positive input end connected to the first output end of the shunt resistance unit, and has a negative input end connected to the second output end of the shunt resistance unit. The second low-precision current-to-voltage conversion IC converts the current signal under test with the changed current level into a second voltage signal, has a positive input end connected to the second output end of the shunt resistance unit, and has a negative input end connected to the first output end of the shunt resistance unit. The subtracter is connected to the first low-precision current-to-voltage conversion IC and the second low-precision current-to-voltage conversion IC for receiving the first voltage signal and the second voltage signal so as to generate the two-way current measurement signal to be calculated.

In an embodiment, the shunt resistance unit, the first resistance unit, and the second resistance unit each come in form of a variable resistance unit.

Accordingly, a voltage and current measuring device of the present invention enables concurrent voltage and current measurement, enhances expansion, and enables a computer to be connected to a test apparatus and to another peripheral through the test apparatus. Hence, the voltage and current measuring device of the present invention is multipurpose and integrated, speeds up a measurement process, and cuts production costs.

### BRIEF DESCRIPTION

Objectives, features, and advantages of the present invention are hereunder illustrated with specific embodiments in conjunction with the accompanying drawings, in which:

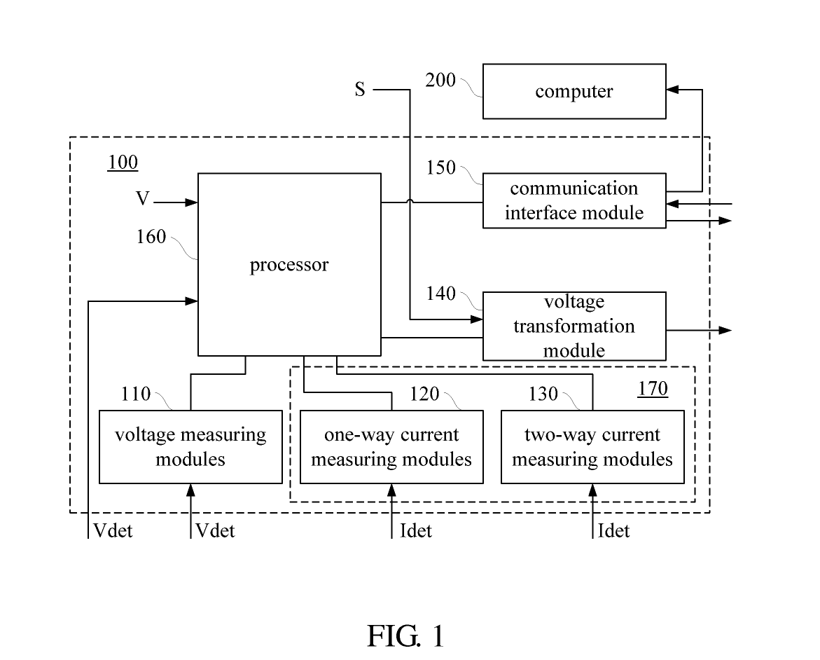

FIG. 1 is a functional block diagram of a voltage and current measuring device according to an embodiment of the present invention;

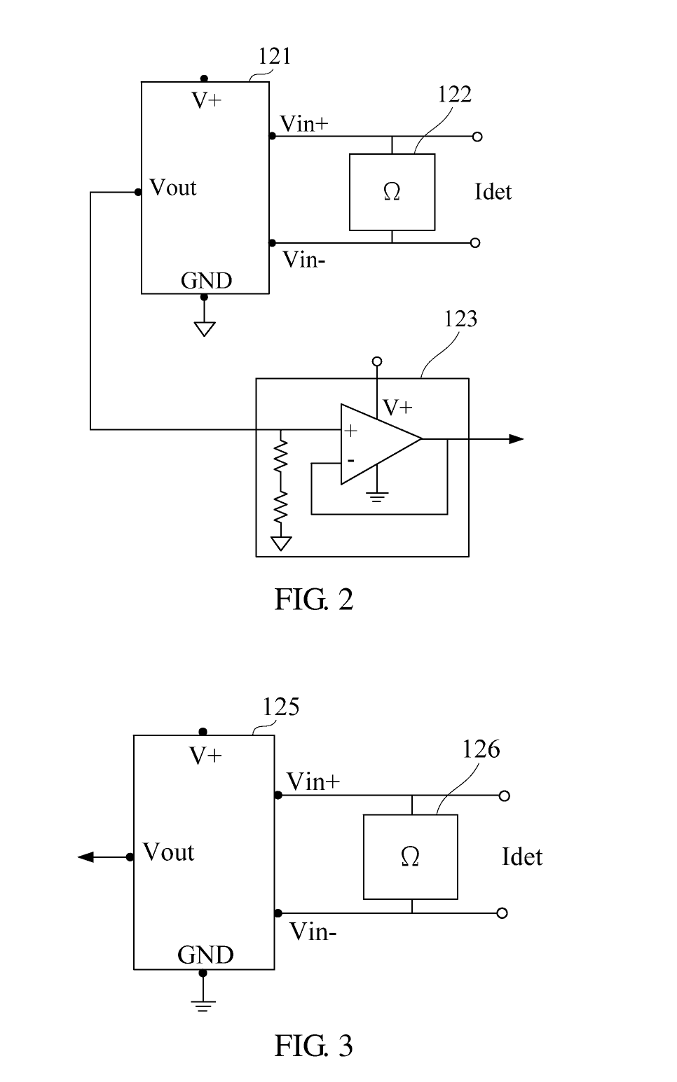

FIG. 2 is a circuit diagram of a high-precision current-to-voltage converter according to an embodiment of the present invention;

FIG. 3 is a circuit diagram of low-precision current-to-voltage converter according to an embodiment of the present invention; and

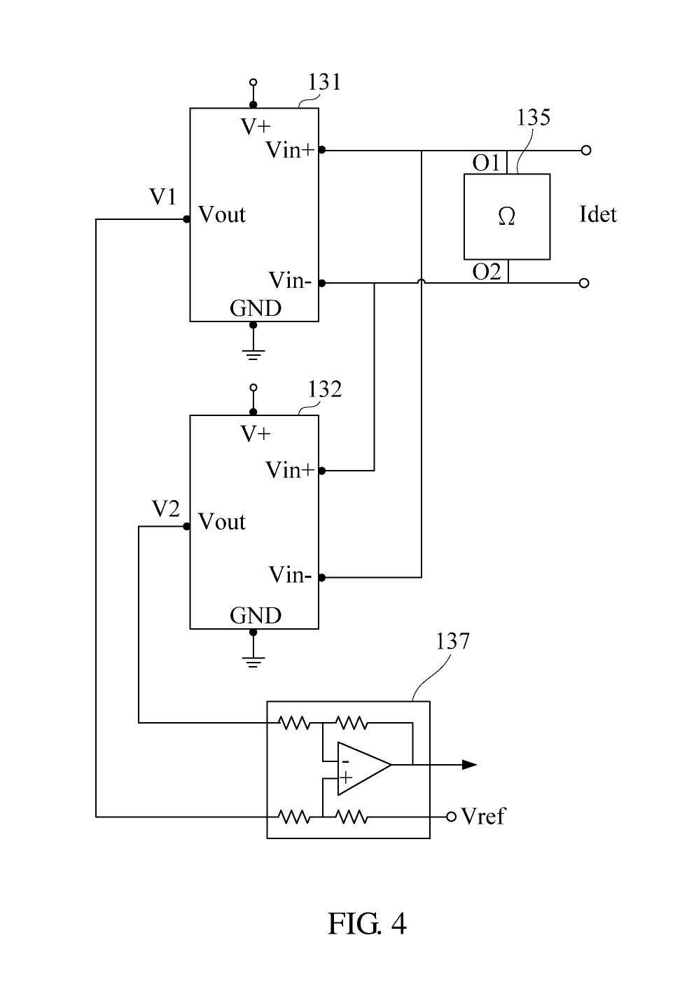

FIG. 4 is a circuit diagram of two-way current measuring modules according to an embodiment of the present invention.

### DETAILED DESCRIPTION

Referring to FIG. 1, there is shown a functional block diagram of a voltage and current measuring device 100 according to an embodiment of the present invention. The voltage and current measuring device 100 comprises a plurality of voltage measuring modules 110, a voltage transformation module 140, a communication interface module 150, a the processor 160, and a plurality of current measuring modules 170. The voltage and current measuring device 100 receives an external power supply S. The power supply S, coupled with a voltage transformation device (not shown), supplies a required operating voltage to all the components inside the voltage and current measuring device 100. For example, the power supply S supplies the processor 160 with a required preset processor voltage level V. The technical means of converting the power supply into an internal operating voltage of a device is readily understood by persons skilled in the art and thus is not described hereunder for the sake of brevity.

The voltage and current measuring device 100 performs voltage and current measurement based on an incoming plurality of voltage and current signals under test. Input ends of the voltage and current measuring device 100 receive a voltage signal under test Vdet and/or a current signal under test Idet. The received voltage signal under test Vdet and/or current signal under test Idet are/is processed by the processor 160 of the voltage and current measuring device 100, and then a measurement result is sent to a computer 200.

The voltage measuring modules 110 each have a partial voltage resistance unit (not shown). The voltage measuring modules 110 each convert the voltage signal under test Vdet into a voltage measurement signal. The partial voltage resistance unit prevents the voltage level of the voltage measurement signal to be calculated from exceeding the preset processor voltage level of the processor 160 in order to enable the processor 160 to operate. The partial voltage resistance unit of each of the voltage measuring modules 110 performs voltage division on the voltage signal under test Vdet, and then the voltage signal under test Vdet is sent to the processor 160 for analog-to-digital conversion. Eventually, a measurement result is sent to the computer 200 via the communication interface module 150. If the measurement result indicates that the voltage level of an object under test does not exceed the preset processor voltage level of the voltage and current measuring device 100, a user can directly connect the object under test to a voltage measuring and receiving end (not shown) of the processor 160. Hence, by making reference to the incoming voltage signal under test Vdet having a voltage level lower than the preset processor voltage level (such as 3.3V), the processor 160 performs analog-to-digital voltage conversion so as to obtain a measurement result. The incoming voltage and current signals under test of the voltage and current measuring device 100 are subjected to the user's manipulation. The voltage and current measuring device 100 is integrated and thus provides ease of use.

In an embodiment, the partial voltage resistance unit of the voltage measuring modules 110 is a variable resistance unit, and thus the partial voltage resistance unit of the voltage measuring modules 110 is equipped with measurement ports for adjusting a partial voltage ratio as needed.

In an embodiment, the current measuring module 170 comprises a plurality of one-way current measuring modules 120 and/or a plurality of two-way current measuring modules 130. FIG. 1 illustrates one of the two aforesaid options, that is, the current measuring module 170 comprises the plurality of one-way current measuring modules 120 and the plurality of two-way current measuring modules 130.

The one-way current measuring modules 120 each convert the incoming current signal under test Idet into a one-way current measurement signal to be calculated. The one-way current measuring modules 120 each operate when a positive/negative input of the current signal under test Idet is correctly connected to a positive/negative pole of the one-way current measuring modules 120. The one-way current measuring modules 120 work only when correctly connected. The one-way current measuring modules 120 do not yield any measurement result when incorrectly connected, but the anomaly is correctable. In an embodiment, the one-way current measuring modules are each a high-precision current-to-voltage converter or a low-precision current-to-voltage converter.

The two-way current measuring modules 130 each convert the incoming current signal under test Idet into a two-way current measurement signal to be calculated. The two-way current measuring modules 130 each operate regardless of whether the positive/negative input of the current signal under test Idet is correctly connected to a positive/negative pole of the two-way current measuring modules 130.

The voltage transformation module 140 receives and transforms the power supply S so as to provide a plurality of voltages of different voltage levels to peripheral devices. For example, the voltage transformation module 140 of the voltage and current measuring device 100 receives the power supply S of 12V, and then the voltage transformation module 140 transforms the power supply S of 12V into the power supply S of 5.3V and 3.3V, such that the voltage and current measuring device 100 can supply peripheral modules or devices with the power supply S of 12V, 5.3V and 3.3V which are appropriate operating voltages thereof, thereby dispensing with an external power supply which is otherwise required for the peripheral modules or devices. Accordingly, the voltage and current measuring device 100 renders the circuit of a production line simple and easy to tidy up and maintain.

The communication interface module 150 comprises a computer communication interface for connection with the computer 200. The communication interface module 150 further comprises a plurality of additional function expansion interfaces for connection with at least a peripheral control device. For example, the computer communication interface is an RS-232 interface. The additional function expansion interfaces comprise a plurality of universal asynchronous receivers-transmitters (UART). The communication interface module 150 can be connected to a temperature and humidity sensor and a light sensor via the additional function expansion interfaces. The communication interface module 150 can be connected to a LCM, a keyboard, a relay board, or a complex programmable logic device (CPLD) by means of General Purpose Input/Output (GPIO) to further expand its additional functionality.

The processor 160 is connected to the voltage measuring modules 110, the voltage transformation module 140, the communication interface module 150, and the current measuring module 170. By contrast, the processor 160 in the preceding embodiment comprises the one-way current measuring modules 120 and the two-way current measuring modules 130. As mentioned earlier, The preset processor voltage, such as 3.3V, is applied to the processor 160. If the voltage level to be measured is unlikely to exceed the preset processor voltage level, the user can directly send a signal under test to the terminal (not shown) of the processor 160 to allow the processor 160 to receive any one of the voltage signals under test Vdet whenever the voltage level of the received voltage signal under test is lower than the preset processor voltage level, such that analog-to-digital conversion can be directly carried out to obtain a voltage measurement result. The processor 160 receives a measurement signal to be calculated from each module, so as to generate a measurement result; afterward, the communication interface module 150 sends the measurement result thus generated to the computer 200.

Referring to FIG. 2, there is shown a circuit diagram of a high-precision current-to-voltage converter according to an embodiment of the present invention. The circuit diagram of the high-precision current-to-voltage converter comprises a first resistance unit 122, a high-precision current-to-voltage conversion IC 121, and a comparison unit 123. The first resistance unit 122 is a variable resistance unit capable of varying the range of a measured current. The current signal under test Idet is diverted by the first resistance unit 122 and then converted into a voltage signal. The voltage signal enters the high-precision current-to-voltage conversion IC 121 through a positive input end Vin+ and a negative input end Vin− of the high-precision current-to-voltage conversion IC 121. The high-precision current-to-voltage conversion IC 121 is connected to an operation power supply V+ and a ground end GND. The high-precision current-to-voltage conversion IC 121 has an output end Vout connected to the comparison unit 123 for outputting a one-way current measurement signal to be calculated.

Referring to FIG. 3, there is shown a circuit diagram of low-precision current-to-voltage converter according to an embodiment of the present invention. The low-precision current-to-voltage converter comprises a second resistance unit 126 and a low-precision current-to-voltage conversion IC 125. The second resistance unit 126 is a variable resistance unit capable of varying the range of a measured current. The current signal under test Idet is diverted by the second resistance unit 126 and then converted into a voltage signal. The voltage signal enters the low-precision current-to-voltage conversion IC 125 through a positive input end Vin+ and a negative input end Vin− of the low-precision current-to-voltage conversion IC 125. The low-precision current-to-voltage conversion IC 125 is connected to an operation power supply V+ and a ground end GND. The low-precision current-to-voltage conversion IC 125 has an output end Vout through which a one-way current measurement signal to be calculated is sent out. The resistance level of the first resistance unit 122 is higher than the resistance level of the second resistance unit 126. The boosting ratio of the high-precision current-to-voltage conversion IC 121 is larger than the boosting ratio of the low-precision current-to-voltage conversion IC 125.

Referring to FIG. 4, there is shown is a circuit diagram of two-way current measuring modules according to an embodiment of the present invention. The two-way current measuring modules comprises a first low-precision voltage to current conversion IC 131, a second low-precision current-to-voltage conversion IC 132, a shunt resistance unit 135, and a subtracter 137. The shunt resistance unit 135 manifests a preset shunt resistance level and receives the current signal under test Idet to change and suit its current level to a preset current range. The shunt resistance unit 135 has a first output end O1 and a second output end O2.

The first low-precision current-to-voltage conversion IC 131 converts the current signal under test Idet with a changed current level into a first voltage signal V1. The positive input end Vin+ of the first low-precision current-to-voltage conversion IC is connected to the first output end O1 of the shunt resistance unit 135. The negative input end Vin− of the first low-precision current-to-voltage conversion IC 131 is connected to the second output end O2 of the shunt resistance unit 135.

The second low-precision current-to-voltage conversion IC 132 converts the current signal under test Idet with a changed current level into a second voltage signal V2. The positive input end Vin+ of the second low-precision current-to-voltage conversion IC 132 is connected to the second output end O2 of the shunt resistance unit 135. The negative input end Vin− of the second low-precision current-to-voltage conversion IC 132 is connected to the first output end O1 of the shunt resistance unit 135. The subtracter 137 is connected to the first low-precision current-to-voltage conversion IC 131 and the second low-precision current-to-voltage conversion IC 132 for receiving the first voltage signal V1 and the second voltage signal V2 so as to generate the two-way current measurement signal to be calculated. The subtracter 137 compares the first voltage signal V1 and the second voltage signal V2 with a reference voltage Vref to obtain the accurate two-way current measurement signal to be calculated. Referring to FIG. 4, the subtracter 137, which is illustrative of one of many possible variant embodiments, comprises four resistance units and a differential amplifier unit. As shown in FIG. 4, two input signals V1, V2 are input via a non-inverting end and an inverting end of the differential amplifier unit to undergo non-inverting amplification and inverting amplification, respectively. Finally, the output end sends out two differential amplified signals of input voltage, that is, the two-way current measurement signal to be calculated.

Given the circuit in the embodiment shown in FIG. 4, the measurement result remains unaffected, regardless of whether the positive/negative input of the current signal under test is correctly connected to the positive/negative pole of the two-way current measuring modules. That is to say, the user can obtain a measurement result without making inverse connection, thereby speeding up the test process flow.

In conclusion, the present invention provides a voltage and current measuring device that enables concurrent voltage and current measurement, enhances expansion, and effectuates multiple purposes, and thus is effective in speeding up a measurement process and cutting production costs.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A voltage and current measuring device for receiving a power supply, performing voltage and current measurement based on an incoming plurality of voltage and current signals under test, and sending a measurement result to a computer, the voltage and current measuring device having a preset processor voltage level, the voltage and current measuring device comprising:
a plurality of voltage measuring modules each having a partial voltage resistance unit and converting an incoming voltage signal under test into a voltage measurement signal to be calculated, wherein the partial voltage resistance unit prevents a voltage level of the voltage measurement signal to be calculated from exceeding the preset processor voltage level;
a plurality of current measuring modules each converting an incoming current signal under test into a current measurement signal to be calculated;
a voltage transformation module for receiving and transforming the power supply so as to provide a plurality of voltages of different voltage levels;
a communication interface module comprising a computer communication interface for connection with the computer; and
a processor connected to the voltage measuring modules, the current measuring modules, the voltage transformation module, and the communication interface module, operating under the preset processor voltage level, performing voltage measurement on any one or more of the voltage signals under test which has or have a voltage level lower than the preset processor voltage level, receiving the voltage measurement signals to be calculated so as to calculate a measured voltage level, receiving the current measurement signals to be calculated so as to calculate a measured current level, and generating the measurement result.

2. The voltage and current measuring device of claim 1, wherein the partial voltage resistance unit of the voltage measuring modules is a variable resistance unit.

3. The voltage and current measuring device of claim 1, wherein the communication interface module comprises a plurality of additional function expansion interfaces for connection with at least a peripheral control device, and the additional function expansion interfaces comprise a plurality of universal asynchronous receivers-transmitters UART.

4. The voltage and current measuring device of claim 1, wherein the current measuring modules comprise at least one of a plurality of one-way current measuring modules and a plurality of two-way current measuring modules, the plurality of one-way current measuring modules each converting the incoming current signal under test into a one-way current measurement signal to be calculated and operating when a positive/negative input of the incoming current signal under test is correctly connected to a positive/negative pole of the one-way current measuring modules, and the plurality of two-way current measuring modules each converting the incoming current signal under test into a two-way current measurement signal to be calculated and operating regardless of whether the positive/negative input of the incoming current signal under test is correctly connected to a positive/negative pole of the two-way current measuring modules.

5. The voltage and current measuring device of claim 4, wherein the one-way current measuring modules are each one of a high-precision current-to-voltage converter and a low-precision current-to-voltage converter, the high-precision current-to-voltage converter having a first resistance unit and a high-precision current-to-voltage conversion IC, the low-precision current-to-voltage converter having a second resistance unit and a low-precision current-to-voltage conversion IC, wherein a resistance level of the first resistance unit is higher than a resistance level of the second resistance unit, and a boosting ratio of the high-precision current-to-voltage conversion IC is larger than a boosting ratio of the low-precision current-to-voltage conversion IC.

6. The voltage and current measuring device of claim 5, wherein the two-way current measuring modules each comprising:
a shunt resistance unit manifesting a preset shunt resistance level, adapted to receive the current signal under test and changing a current level thereof to a preset current range, and having a first output end and a second output end;
a first low-precision current-to-voltage conversion IC converting the current signal under test with the changed current level into a first voltage signal, having a positive input end connected to the first output end of the shunt resistance unit, and having a negative input end connected to the second output end of the shunt resistance unit;
a second low-precision current-to-voltage conversion IC converting the current signal under test with the changed current level into a second voltage signal, having a positive input end connected to the second output end of the shunt resistance unit, and having a negative input end connected to the first output end of the shunt resistance unit; and
a subtracter connected to the first low-precision current-to-voltage conversion IC and the second low-precision current-to-voltage conversion IC for receiving the first voltage signal and the second voltage signal so as to generate the two-way current measurement signal to be calculated.

7. The voltage and current measuring device of claim 6, wherein the shunt resistance unit, the first resistance unit, and the second resistance unit each come in form of a variable resistance unit.
